(19) United States
(12) Patent Application Publication
(10) Pub. No.: US 2006/0068603 A1
(43) Pub. Date: Mar. 30, 2006

(54) A METHOD FOR FORMING A THIN COMPLETE HIGH-PERMITTIVITY DIELECTRIC LAYER

(75) Inventor: Cory Wajda, Sand Lake, NY (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TOKYO ELECTRON LIMITED, Tokyo (JP)

(21) Appl. No.: 10/711,721

(22) Filed: Sep. 30, 2004

(51) Int. Cl. H01L 21/31

(52) U.S. Cl. 438/785

(57) ABSTRACT

A method for forming a thin complete high-k layer for semiconductor applications. The method includes providing a substrate in a process chamber, depositing a thick complete high-k layer on the substrate, and thinning the deposited high-k layer to form a thin complete high-k layer on the substrate. Alternately, the substrate can contain an interface layer between the substrate and the high-k layer. The thinning can be performed by exposing the thick high-k layer to a reactive plasma etch process or, alternately, a plasma process capable of modifying a portion of the thick high-k layer and subsequently removing the modified portion of the thick high-k layer using wet processing.

### FIELD OF THE INVENTION

The present invention is related to semiconductor processing, and more particularly, to a method for forming a thin complete high-permittivity dielectric layer for semiconductor applications.

### BACKGROUND OF THE INVENTION

In the semiconductor industry, the minimum feature sizes of microelectronic devices are approaching the deep sub-micron regime to meet the demand for faster, lower power microprocessors and digital circuits. Downscaling of complementary metal-oxide semiconductor (CMOS) devices imposes scaling constraints on the dielectric material in gate stacks, where the thickness of the standard SiO₂ gate oxide dielectric layer is approaching the limit (˜10 Angstroms (Å)) at which tunneling currents significantly impact transistor performance.

To increase device reliability and reduce electron leakage from the gate electrode to the transistor channel, semiconductor transistor technology is using high-permittivity dielectric materials (also referred to herein as “high-k” materials) in gate stacks that allow increased physical thickness of the gate dielectric layer while maintaining an equivalent gate oxide thickness (EOT) of less than about 15 Å. EOT is a relative measure of the thickness of a gate dielectric material with respect to the actual physical thickness of a SiO₂ layer having the same capacitance value as the gate dielectric material. Since capacitance is directly proportional to the dielectric constant and inversely proportional the thickness of the layer, it follows that an increase in dielectric constant allows for an increase in thickness in order to maintain the same capacitance.

Dielectric materials featuring a dielectric constant greater than that of SiO₂ (k˜3.9) are commonly referred to as high-k materials. In addition, high-k materials may refer to dielectric materials that are deposited onto the substrate (e.g., HfO₂, ZrO₂) rather than dielectric materials that are grown on the surface of the substrate (e.g., SiO₂, SiOₓN_{y}). High-k materials may incorporate metallic silicates or oxides, including Ta₂O₅ (k˜26), TiO₂ (k˜80), ZrO₂ (k˜25), Al₂O₃ (k˜9), HfSiOₓ (k˜4-25), and HfO₂ (k˜25). Manufacturing of features having sizes in the sub-micron regime can require formation of very thin high-k layers (i.e., having thickness less than about 100 Å) with a minimum of gaps or variations in the thickness of the high-k layer.

### SUMMARY OF THE INVENTION

A method is provided for forming a thin complete high-k layer on a substrate. The method provides a process for forming a thin complete high-k layer with a minimum of gaps and with good thickness uniformity. The method includes providing a substrate in a process chamber, depositing a thick complete high-k layer on the substrate, and thinning the deposited high-k layer to form a thin complete high-k layer on the substrate. The thinning can include a reactive plasma etch process to remove a portion of the deposited high-k layer or, alternately, a plasma process to modify/thin the deposited high-k layer and remove the modified portion of the high-k layer using wet processing.

In one embodiment of the invention, the thick complete high-k layer can have a thickness between about 30 Å and about 200 Å. Alternately, the thickness of the thick complete high-k layer can be between about 50 Å and about 100 Å. It may be appreciated that the minimum thickness necessary to form a complete layer may differ from one high-k material to another. The minimum thickness, however, is typically greater than the desired thickness for that high-k material in the gate stack. Thus, after the complete high-k layer is achieved, a portion of that layer is removed, i.e., thinned, to leave a complete high-k layer of the thinner desired thickness. In one embodiment of the invention, the thin complete high-k layer can have a thickness between about 5 A and about 50 A. Alternately, the thickness of the thin complete high-k layer can between about 30 Å and about 40 Å.

### BRIEF DESCRIPTION OF THE DRAWINGS

In the accompanied drawings:

FIGS. 1A-1B show schematic cross-sectional representations of gate stacks containing a high-k layer made according to embodiments of the present invention;

FIGS. 2A-2D schematically show formation of a thin complete high-k layer on a substrate according to an embodiment of the present invention;

FIGS. 2E-2F schematically show formation of a thin complete high-k layer on a substrate according to another embodiment of the present invention;

FIG. 3 is a flowchart illustrating a method of forming a thin complete high-k layer according to an embodiment of the invention;

FIG. 4 schematically shows a processing system configured for depositing a high-k layer according to an embodiment of the invention;

FIG. 5 schematically shows a plasma processing system configured for processing a high-k layer according to an embodiment of the present invention;

FIG. 6 schematically shows a plasma processing system configured for processing a high-k layer according to another embodiment of the present invention;

FIG. 7 schematically shows a plasma processing system configured for processing a high-k layer according to yet another embodiment of the present invention; and

FIG. 8 schematically shows a plasma processing system configured for processing a high-k layer according to still another embodiment of the present invention.

### DETAILED DESCRIPTION OF EMBODIMENTS OF THE INVENTION

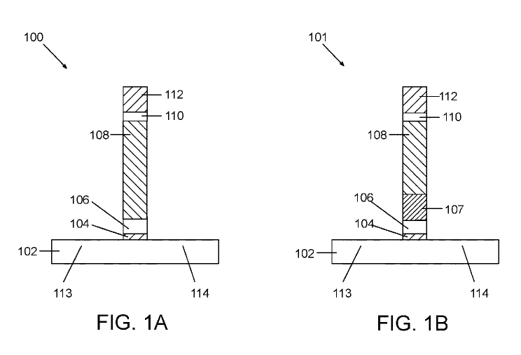

FIGS. 1A-1B show schematic cross-sectional representations of gate stacks containing a high-k layer made according to embodiments of the present invention. FIG. 1A shows a partially completed gate stack 100 after an anisotropic plasma etch process that forms the etch features shown. The exemplary gate stack 100 contains a substrate 102 having a source region 113 and a drain region 114, a dielectric interface layer 104, a high-k layer 106, a gate electrode layer 108, an anti-reflective coating (ARC)/hardmask layer 110, and a photoresist layer 112. The substrate 102 can, for example, contain Si, Ge, Si/Ge, or GaAs. In one embodiment of the invention, the substrate 102 can be a Si substrate containing epitaxial Si or poly-Si. A Si substrate can be of n- or p-type, depending on the type of device being formed. The substrate 102 can be of any size, for example a 200 mm substrate, a 300 mm substrate, or an even larger substrate.

The dielectric interface layer 104 can, for example, be an oxide layer (e.g., SiO₂), a nitride layer (e.g., SiNₓ), or an oxynitride layer (e.g., SiOₓN_{y}), or a combination thereof. The dielectric interface layer 104 at the substrate surface can preserve interface state characteristics and form an interface with good electrical properties between the high-k layer 106 and the substrate 102. However, the presence of an interface layer 104 lowers the overall dielectric constant of the gate stack 100 and, therefore, when integrated with the thin high-k layer 106, the interface layer 104 may need to be very thin. Integrated circuits containing a Si substrate commonly employ SiO₂ and/or SiOₓN_{y} interface layers that can have excellent electrical properties, including high electron mobility and low electron trap densities. Currently, gate stacks containing a high-k layer formed on SiO₂ and/or SiOₓN_{y} interface layers can require an interface layer thickness of only about 5-10 Å.

The high-k layer is formed in accordance with the method of the present invention, as described in further detail below. The high-k layer 106 can, for example, contain a metal oxide or a metal silicate, including Ta₂O₅, TiO₂, ZrO₂, Al₂O₃, Y₂O₃, HfSiOₓ, HfO₂, ZrSiOₓ, TaSiOₓ, SrOₓ, SrSiOₓ, LaOₓ, LaSiOₓ, YOₓ, or YSiOₓ, or combinations of two or more thereof. The thickness of the high-k layer 106 can, for example, be between about 5 Å and about 50 Å, and can be about 30-40 Å. The gate electrode layer 108 in FIG. 1A can, for example, be doped poly-Si. Selection of the appropriate ARC/hardmask layer 110 and photoresist layer 112 that enables formation of etch features with the desired dimensions are well known to persons skilled in the art of lithography and plasma etching.

FIG. 1B shows another partially completed gate stack 101 after an anisotropic plasma etch process that forms the etch features shown. The gate stack 101 contains a metal gate electrode layer 107 in addition to the materials layers shown in FIG. 1A. The metal gate electrode layer 107 can, for example, be about 100 A thick and can contain W, WN, Al, TaN, TaSiN, HfN, HfSiN, TiN, TiSiN, Re, Ru, or SiGe. The introduction of metal gate electrodes to replace or to be integrated with the traditional poly-Si gate electrode layer can bring about several advantages, including elimination of the poly-silicon gate depletion effect, reduction in sheet resistance, better reliability and potentially better thermal stability on advanced high-k layers.

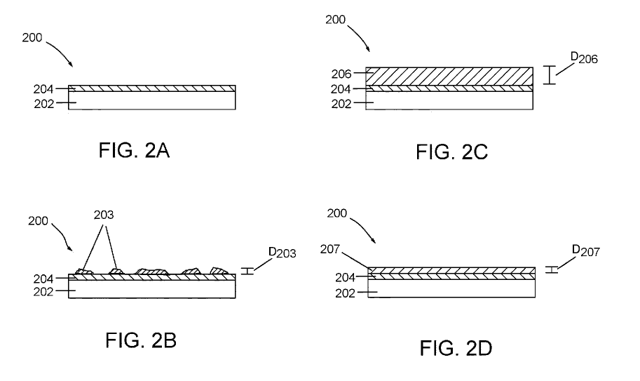

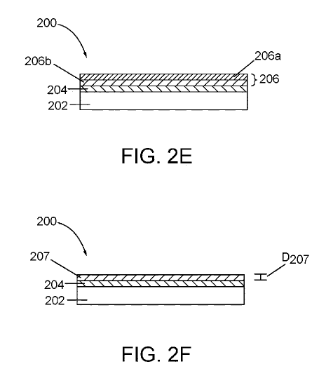

FIGS. 2A-2D schematically show formation of a thin complete high-k layer on a substrate according to an embodiment of the present invention. FIG. 2A shows a substrate structure 200 including a substrate 202 having a dielectric interface layer 204 formed thereon. As described above, the interface layer 204 can, for example, be an oxide layer, a nitride layer, or an oxynitride layer, or a combination thereof. Processes for forming oxide, nitride, and oxynitride layers are well known to those skilled in the of semiconductor processing. Alternately, the interface layer 204 may not be present.

In general, different modes of film growth can be encountered when depositing a thin film on substrate. A Frank-Van der Merwe thin film growth is characterized by an ideal epitaxial layer by layer growth on a substrate, whereas a Volmer-Weber thin film growth is characterized by island growth on a substrate. A Stranski-Krastanov thin film growth is characterized by island growth coupled with a layer by layer growth on a substrate. With high-k materials, the Volmer-Weber and/or Stranski-Krastanov growth mode is/are frequently observed.

FIG. 2B shows islands of high-k material 203 formed on the interface layer 204. As described above, the high-k material 203 can contain a metal oxide or a metal silicate, or a combination thereof. FIG. 2B illustrates Volmer-Weber growth when depositing a high-k material 203 on an interface layer 204. Instead of forming a thin complete high-k layer with no gaps and good thickness uniformity (Frank-Van der Merwe growth mode), the deposition process depicted in FIG. 2B forms islands of the deposited high-k material 203 with gaps that expose the interface layer 204 between the high-k islands. In FIG. 2B, the islands have a thickness D₂₀₃ that can, for example, be between about 5 Å and about 50 Å, or greater. The thickness D₂₀₃ and the lateral size of the islands can vary depending on the type of the high-k material 203 and the type of the interface layer 204. Furthermore, the thickness D₂₀₃ and the lateral size of the islands can depend on the deposition and annealing conditions of the high-k material 203 and the interface layer 204.

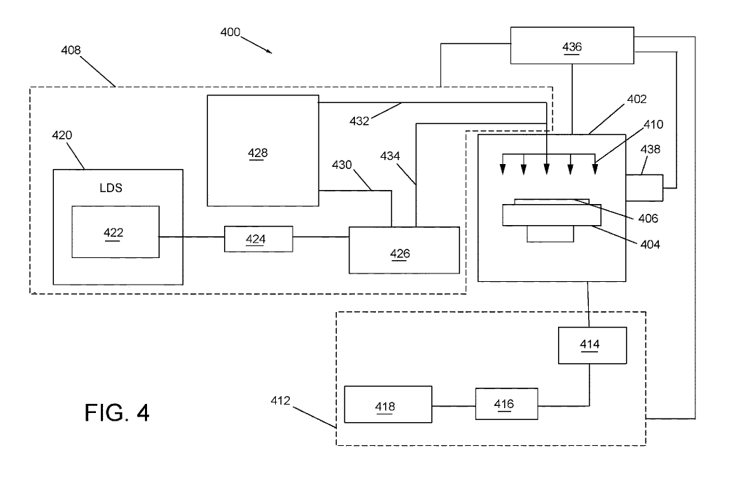

The high-k material 203 can, for example, be deposited onto the interface layer 204 using various deposition processes that are well-known to persons skilled in the art of thin film deposition, including, but not limited to, thermal chemical vapor deposition (TCVD), plasma-enhanced chemical vapor deposition (PECVD), atomic layer deposition (ALD), and physical vapor deposition (PVD). An exemplary processing system configured for depositing a high-k layer on a substrate in a TCVD process is shown and described in FIG. 4.

One requirement for integrating a high-k material into the substrate structure 200 is that the high-k material 203 form a complete layer on the interface layer 204 (or on the substrate 202 when an interface layer is not present) and that the complete layer have good thickness uniformity. A complete high-k layer with good thickness uniformity is required to increase device reliability and reduce electron leakage from a gate electrode overlying the high-k material 203 to the substrate 202.

Further deposition of the high-k material onto the substrate structure 200 in FIG. 2B, results in a thick complete high-k layer 206 on the interface layer 204, as shown in FIG. 2C. A complete high-k layer is referred to herein as a high-k layer that completely covers, e.g., is continuous over, the underlying interface layer 204 or the substrate 202 without any gaps. The thick complete high-k layer 206 can, for example, have a thickness D₂₀₆ between about 30 Å and about 200 Å with good thickness uniformity. As noted above, the minimum thickness to which the high-k layer must be deposited before a complete layer is achieved may vary among high-k materials, but generally is greater than 50 Å. However, the thickness D₂₀₆ can be too great for many semiconductor devices that can, for example, require a thickness D₂₀₆ that is between about 10 Å and about 40 Å. A thin complete high-k layer with a thickness less than D₂₀₆ cannot simply be deposited onto the interface layer 204. Thus, by the method of the present invention, the complete high-k layer of thickness D₂₀₆ is first formed, then thinned to achieve the desired thickness less than D₂₀₆.

FIG. 2D shows formation of a thin complete high-k layer 207 according to an embodiment of the invention. The thin complete high-k layer 207 is formed by first depositing the thick complete high-k layer 206 shown in FIG. 2C, and then thinning the layer 206 to form a thin complete high-k layer 207 with a thickness D₂₀₇, where the thickness D₂₀₇ is less than D₂₀₆. According to one embodiment of the invention, the thickness D₂₀₆ can be between about 30 Å and about 200 Å. Alternately, the thickness D₂₀₆ can be between about 50 A and about 100 A. According to one embodiment of the invention, the thickness D₂₀₇ can be between about 5 Å and about 50 ÅA. Alternately, the thickness D₂₀₇ can be between about 30 Å and about 40 Å.

According to an embodiment of the invention, thinning of the thick complete high-k layer 206 can be performed in a plasma processing system. According to an embodiment of the present invention, the thinning can be carried out by reactive plasma etching of the high-k layer 206 using aggressive halogen-containing gases that react with the high-k layer 206 to form halogen-containing etch products that are removed from the plasma processing system. Halogen-containing gases with general formulas HX, X₂, CₓX_{z}, or CₓH_{y}X_{z}, where X is a halogen, can be used.

FIGS. 2E-2F schematically show formation of a thin complete high-k layer on a substrate according to another embodiment of the present invention. Thinning of the thick complete high-k layer 206 in FIG. 2C can be performed by a plasma modifying/thinning process that is combined with wet processing. Ion bombardment can be used to partially remove and/or modify the high-k layer 206 in FIG. 2F without completely removing it.

FIG. 2E schematically shows a modified portion 206a following a plasma modifying/thinning process performed on the high-k layer 206. In one example, the plasma can contain a reactive gas, for example HBr or HCl, and an inert gas. In another example, the plasma may only contain chemically inert gas species that are non-reactive towards the high-k layer 206 in a plasma environment, but where the ions have sufficient energy to effectively disrupt and/or thin the high-k layer 206 so that a subsequent wet etching process is able to efficiently remove the disrupted (modified) portion 206a from the un-modified portion 206b. The inert gas can, for example, contain the noble gases He, Ne, Ar, Kr, and Xe. The exact effect of the plasma modifying/thinning process can depend on the gases used in the plasma processing. It is believed that the plasma processing may increase the amorphous content of the high-k layer 206 and possibly break chemical bonds that create atomic fragments in the portion 206a. The suggested disruption of the molecular structure of the portion 206a during plasma processing can allow for a greater choice of wet etch chemistries that have high etch selectivity for the modified portion 206a compared to the un-modified portion 206b, the interface layer 204, and the substrate 202. The subsequent wet etch process can, for example, utilize hot sulfuric acid (H₂SO₄) or hydrofluoric acid (HF_{(aq)}) to remove the modified portion 206a from the un-modified portion 206b, thereby forming a thin complete high-k layer 207 with a thickness D₂₀₇. Since the high-k layer 206b is not traversed during the plasma modifying/thinning process, the likelihood of damage occurring to the underlying interface layer 204 and substrate 202 is reduced. Wet processing for removing thin layers from substrates is well known to artisans skilled in the art of semiconductor processing.

Plasma processing of the high-k layer 206 can lead to an increase in the thickness of the interface layer 204. A method for minimizing the increase in the thickness of the interface layer 204 during plasma processing of the high-k layer 206 is described in U.S. patent application Ser. No. ______, filed on even date herewith and titled “A METHOD AND SYSTEM FOR FORMING A FEATURE IN A HIGH-K LAYER, the content of which is hereby incorporated by reference in its entirety.

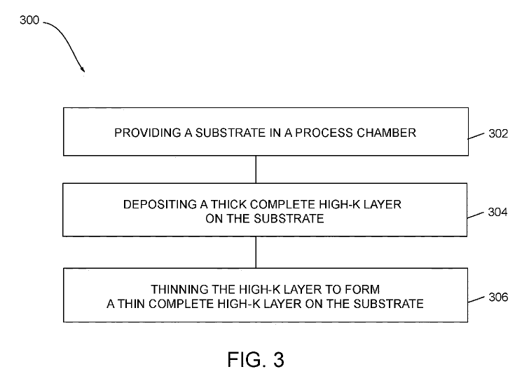

FIG. 3 is a flowchart illustrating a method of forming a thin complete high-k layer according to an embodiment of the invention. The process 300 includes at 302, providing a substrate in a process chamber configured for depositing a high-k layer on the substrate. In one embodiment of the invention, the substrate can further contain an interface layer formed on the substrate. At 304, a high-k layer is deposited on the substrate. The deposition process is carried out for a desired amount of time to form a thick complete high-k layer on the substrate. At 306, the thick complete high-k layer is thinned to form a thin complete high-k layer. In one embodiment of the invention, the thinning can be performed using reactive plasma etching. In another embodiment of the invention, the plasma processing can include a plasma modifying/thinning process followed by wet processing for removing the modified portion of the high-k layer from the unmodified portion of the high-k layer. As would be appreciated by those skilled in the art, each of the steps or stages in the flowchart of FIG. 3 may encompass one or more separate steps and/or operations. Accordingly, the recitation of only three steps in 302, 304, 306 should not be understood to limit the method of the present invention solely to three steps or stages. Moreover, each representative step or stage 302, 304, 306 should not be understood to be limited to only a single process.

FIG. 4 schematically shows a plasma processing system configured for depositing a high-k layer on a substrate according to an embodiment of the invention. In particular, the processing system 400 is configured for depositing a high-k layer on a substrate 406 in a TCVD process. The processing system 400 comprises a process chamber 402, a gas injection system 408, a pumping system 412, a process monitoring system 438, and a controller 436. The process chamber 402 comprises a substrate holder 404, upon which a substrate 406 to be processed is affixed. Substrate 406 can be transferred into and out of process chamber 402 through a slot valve (not shown) and chamber feed-through (not shown) via robotic substrate transfer system where it is received by substrate lift pins (not shown) housed within substrate holder 404 and mechanically translated by devices housed therein. Once the substrate 406 is received from the substrate transfer system, it is lowered to an upper surface of the substrate holder 404. The substrate 406 can, for example, be a Si substrate and, depending on the type of device being formed, can, for example, consist of a substrate of any diameter, for example, a 200 mm substrate, a 300 mm substrate, or an even larger substrate.

The substrate 406 can be affixed to the substrate holder 404 via an electrostatic clamp (not shown). Furthermore, the substrate holder 404 further includes a cooling system (not shown) including a re-circulating coolant flow that receives heat from the substrate holder 404 and transfers heat to a heat exchanger system (not shown), or when heating, transfers heat from the heat exchanger system. Moreover, gas may be delivered to the backside of the substrate 406 to improve the gas-gap thermal conductance between the substrate 406 and the substrate holder 404. Such a system is utilized when temperature control of the substrate 406 is required at elevated or reduced temperatures.

A gas injection system 408 introduces process gas 410 to the process chamber 402. The gas injection system 408 comprises a liquid delivery system (LDS) 420 that includes at least one precursor source 422 containing a high-k precursor material. The introduction of precursor material into vaporizer 426 can be controlled using a liquid mass flow controller (LMFC) 424. Vaporized precursor material from vaporizer 426 can be mixed with a carrier gas delivered via gas line 430 from gas box 428 and the mixture can be delivered to the process chamber 402 via gas line 434. Purge gases (e.g., Ar) and other gases (e.g., O₂, N₂, and H₂O) can be delivered directly from the gas box 428 to the process chamber 402 utilizing additional gas line 432. The gas injection system 408 allows independent control over the delivery of process gas 410 to the process chamber 402 from ex-situ gas sources. The gas injection system 408 can employ an effusive gas distribution source such as a showerhead in the process chamber 402. In an alternate embodiment of the invention, the gas injection system 408 can be configured for vaporizing a solid precursor material and delivering the vaporized precursor material via gas line 434 to the process chamber 402.

A vacuum pumping system 412 comprises a vacuum pump 418, a trap 416, and automatic pressure controller (APC) 414. The vacuum pump 418 can include a turbo-molecular vacuum pump (TMP) capable of a pumping speed up to 5000 liters per second (and greater) and a gate valve for throttling the chamber pressure. Alternatively, the vacuum pump 418 can include a dry pump. During processing, process gas 410 can be introduced into the process chamber 402 via the gas injection system 408 and the process pressure is adjusted by the APC 414. The trap 416 can collect un-reacted precursor material and by-products from the process chamber 402.

A controller 436 includes a microprocessor, a memory, and a digital I/O port capable of generating control voltages sufficient to communicate and activate inputs of the processing system 400 as well as monitor outputs from the processing system 400. Moreover, the controller 436 is coupled to and exchanges information with the process chamber 402, the process monitoring system 438, the gas injection system 408, and the vacuum pumping system 412. A program stored in the memory is utilized to control the aforementioned components of a processing system 400 according to a stored process recipe. One example of controller 436 is a DELL PRECISION WORKSTATION 610™, available from Dell Corporation, Dallas, Tex.

The process monitoring system 438 can, for example, measure gaseous species, such as precursors, reaction by-products, and other gases in the processing environment. The process monitoring system 438 components in FIG. 4 are attached to the process chamber 402. In an alternate embodiment, some components of the process monitoring system 438 are located downstream from the process chamber 402. The process monitoring system 438 can be used with controller 436 to determine the status of the deposition process and provide feedback to ensure process compliance.

The substrate 406 is exposed to the process gas for a time period that results in the desired deposition of the high-k layer. Process conditions that enable the desired deposition of the high-k layer may be determined by direct experimentation and/or design of experiments. For example, adjustable process parameters can comprise time, temperature (e.g., substrate temperature), process pressure, process gases and relative gas flows of the process gases, among other parameters. The process parameter space for the deposition process can, for example, utilize a chamber pressure less than about 10 Torr, a process gas flow rate less than 2000 sccm, a precursor gas flow rate less than 1000 sccm, and a substrate temperature greater than about 200° C.

When depositing a metal oxide high-k dielectric layer using TCVD, a process gas comprising a metal-containing precursor is introduced into a processing chamber containing a heated substrate to be processed. The substrate is exposed to the process gas for a time period that results in the desired deposition of the metal oxide high-k layer. Metal oxide high-k materials can be deposited from metal oxide chemical vapor deposition (MOCVD) precursors. In the exemplary case of Hf and Zr (M=Hf, Zr), the MOCVD precursors can comprise metal alkoxides (e.g., M(OR)ₙ) and metal alkylamides (e.g., M(NR)₄) that can deposit metal oxide layers at substrate temperatures above about 300° C. The metal alkoxide precursors can, for example, be selected from four-coordinate complexes such as M(OMe)₄, M(OEt)₄, M(OPr)₄, and M(OBu^{t})₄, where Me is methyl, Et is ethyl, Pr is propyl, and Bu^{t} is tert-butyl. The metal alkylamide precursor can, for example, be selected from M(NMe₂)₄, M(NEt₂)₄, and M(NPr₂)₄. The MOCVD precursor can also be selected from six-coordinate complexes such as M(OBu^{t})₂(MMP)₂ and M(MMP)₄, where MMP=OCMe₂CH₂OMe. As would be appreciated by those skilled in the art, other metal-containing precursors may be employed without departing from the scope of the invention.

Hf(OBu^{t})₄ is a hafnium-containing MOCVD precursor that enables deposition of HfO₂ high-k layers for device fabrication. Hf(OBu^{t})₄ comprises a relatively high vapor pressure (Pᵥₐₚ˜1 Torr at 65° C.), and therefore requires minimal heating of the precursor and precursor delivery lines for delivering the precursor to the process chamber. In addition, Hf(OBu^{t})₄ does not decompose at temperatures below about 200° C., which significantly reduces precursor decomposition due to interactions with chamber walls and gas phase reactions. The Hf(OBu^{t})₄ precursor can, for example, be delivered to the process chamber using a liquid injection system comprising a vaporizer that is maintained at a temperature of 50° C., or higher. An inert carrier gas (e.g., He, N₂) can be mixed with the vaporized precursor to aid in the delivery of the precursor to the process chamber.

Hf(OBu^{t})₄ contains both the Hf metal and the oxygen required to grow stoichiometric HfO₂ layers under proper process conditions, thereby providing reduced process complexity. Alternatively, the process gas containing the MOCVD precursor can further contain a second oxygen-containing gas as a second source of oxygen.

Similarly, metal silicate high-k materials can be deposited from MOCVD precursors and a silicon-containing gas. For example, a HfSiOₓ high-k layer can be deposited on a substrate using Hf(OBu^{t})₄ precursor and a silicon-containing gas. The silicon-containing gas can, for example, contain silane (SiH₄), disilane (Si₂H₆), dichlorosilane (SiH₂Cl₂), hexachlorodisilane (Si₂Cl₆), bis (tertbutylamino) silane (SiH₂(NBu^{t})₂), or tetrakis (dimethylamino) silane (Si(NMe₂)₄), tetraethylorthosilicate (TEOS, Si(OEt)₄)), or a combination of two or more thereof.

The process gas can further comprise a carrier gas (e.g., an inert gas) and an oxidizing gas. The inert gas can include at least one of Ar, He, Ne, Kr, Xe, and N₂. The addition of inert gas can, for example, dilute the process gas or adjust the process gas partial pressure(s). The oxidizing gas can, for example, contain an oxygen-containing gas comprising at least one of O₂, O₃, H₂O, H₂O₂, NO, NO₂, and N₂O. The role of the oxygen-containing gas in the deposition process can be to fill any oxygen vacancies in the metal oxide or metal silicate high-k layer, or to chemically modify the metal oxide precursor. The modification can involve interaction of the oxygen-containing gas with the metal oxide precursor in the gas phase or on the deposition surface.

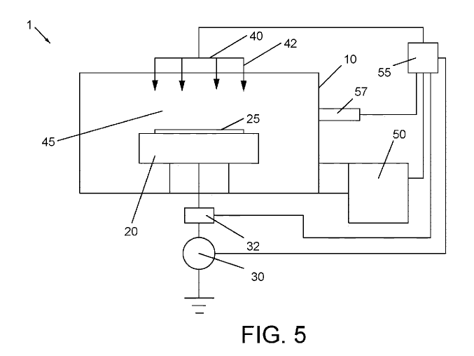

FIGS. 5-8 schematically show plasma processing systems that may be utilized to plasma process a thick complete high-k layer to form a thin complete high-k layer according to embodiments of the invention. FIG. 5 schematically shows a plasma processing system configured for processing a high-k layer according to an embodiment of the invention. The plasma processing system 1 depicted in FIG. 5 is capable of sustaining a plasma and includes a plasma process chamber 10 configured to facilitate the generation of plasma in processing region 45. The plasma processing system 1 further comprises a substrate holder 20 upon which a substrate 25 to be processed is affixed, a gas injection system 40 for introducing process gases 42 to the plasma process chamber 10, an RF generator 30 and impedance match network 32 for delivering RF power to the substrate holder 20, a vacuum pumping system 50, a plasma monitor system 57, and a controller 55.

The gas injection system 40 allows independent control over the delivery of process gases to the process chamber from ex-situ gas sources. An ionizable gas or mixture of gases is introduced via the gas injection system 40 and the process pressure is adjusted. For example, controller 55 is used to control the vacuum pumping system 50 and gas injection system 40.

Substrate 25 is transferred into and out of chamber 10 through a slot valve (not shown) and chamber feed-through (not shown) via a robotic substrate transfer system where it is received by substrate lift pins (not shown) housed within substrate holder 20 and mechanically translated by devices housed therein. Once the substrate 25 is received from the substrate transfer system, it is lowered to an upper surface of the substrate holder 20.

In an alternate embodiment, the substrate 25 is affixed to the substrate holder 20 via an electrostatic clamp (not shown). Furthermore, the substrate holder 20 further includes a cooling system (not shown) including a re-circulating coolant flow that receives heat from the substrate holder 20 and transfers heat to a heat exchanger system (not shown), or when heating, transfers heat from the heat exchanger system. Moreover, gas may be delivered to the backside of the substrate 25 to improve the gas-gap thermal conductance between the substrate 25 and the substrate holder 20. Such a system is utilized when temperature control of the substrate is required at elevated or reduced temperatures. For example, temperature control of the substrate may be useful at temperatures in excess of the steady-state temperature achieved due to a balance of the heat flux delivered to the substrate 25 from the plasma and the heat flux removed from substrate 25 by conduction to the substrate holder 20. In other embodiments, heating elements, such as resistive heating elements, or thermo-electric heaters/coolers are included.

In the embodiment, shown in FIG. 5, the substrate holder 20 can further serve as an electrode through which radio frequency (RF) power is coupled to plasma in the processing region 45. For example, the substrate holder 20 can be electrically biased at a RF voltage via the transmission of RF power from an RF generator 30 through an impedance match network 32 to the substrate holder 20. The RF bias serves to heat electrons and, thereby, form and maintain plasma. In this configuration, the system operates as a RIE reactor, wherein the chamber and upper gas injection electrode serve as ground surfaces. A typical frequency for the RF bias ranges from 1 MHz to 100 MHz and is preferably 13.56 MHz.

In an alternate embodiment, RF power can be applied to the substrate holder electrode at multiple frequencies. Furthermore, the impedance match network 32 serves to maximize the transfer of RF power to plasma in processing chamber 10 by minimizing the reflected power. Match network topologies (e.g., L-type, n-type, T-type) and automatic control methods are known in the art.

With continuing reference to FIG. 5, a process gas 42 is introduced to the processing region 45 through the gas injection system 40. Gas injection system 40 can include a showerhead, wherein the process gas 42 is supplied from a gas delivery system (not shown) to the processing region 45 through a gas injection plenum (not shown), a series of baffle plates (not shown) and a multi-orifice showerhead gas injection plate (not shown).

Vacuum pump system 50 can include a turbo-molecular vacuum pump (TMP) capable of a pumping speed up to 5000 liters per second (and greater), and a gate valve for throttling the chamber pressure. In conventional plasma processing devices utilized for dry plasma etch, a 1000 to 3000 liter per second TMP is employed. TMPs are useful for low pressure processing, typically less than 50 mTorr. For high pressure processing (i.e., greater than 100 mTorr), a mechanical booster pump and dry roughing pump are used.

A controller 55 includes a microprocessor, a memory, and a digital I/O port capable of generating control voltages sufficient to communicate and activate inputs to the plasma processing system 1 as well as monitor outputs from the plasma processing system 1. Moreover, the controller 55 is coupled to and exchanges information with the RF generator 30, the impedance match network 32, the gas injection system 40, plasma monitor system 57, and the vacuum pump system 50. A program stored in the memory is utilized to control the aforementioned components of a plasma processing system 1 according to a stored process recipe. One example of controller 55 is a digital signal processor (DSP); model number TMS320, available from Texas Instruments, Dallas, Tex.

The plasma monitor system 57 can comprise, for example, an optical emission spectroscopy (OES) system to measure excited particles in the plasma environment and/or a plasma diagnostic system, such as a Langmuir probe, for measuring plasma density. The plasma monitor system 57 can be used with controller 55 to determine the status of the etching process and provide feedback to ensure process compliance. Alternately, plasma monitor system 57 can comprise a microwave and/or a RF diagnostic system.

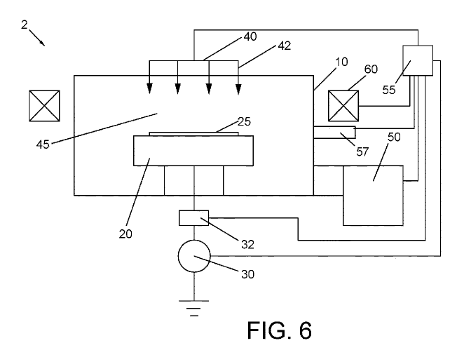

FIG. 6 schematically shows a plasma processing system configured for processing a high-k layer according to another embodiment of the invention. The plasma processing system 2 of FIG. 6 includes the components of system 1 depicted in and described with reference to FIG. 5, and further includes either a mechanically or electrically rotating DC magnetic field system 60 to potentially increase plasma density and/or improve plasma processing uniformity. Moreover, the controller 55 is coupled to the rotating magnetic field system 60 in order to regulate the speed of rotation and the field strength.

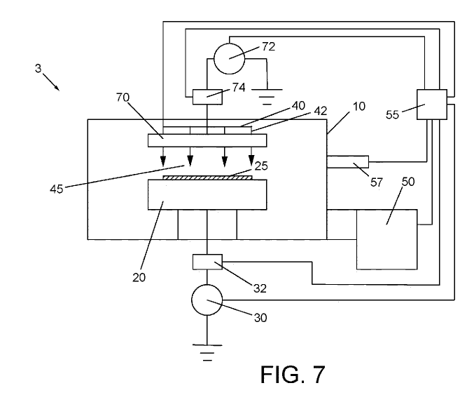

FIG. 7 schematically shows a plasma processing system configured for processing a high-k layer according to yet another embodiment of the invention. The plasma processing system 3 of FIG. 7 includes the components of system 1 depicted in and described with reference to FIG. 5, and further includes an upper plate electrode 70 to which RF power is coupled from an RF generator 72 through an impedance match network 74. A typical frequency for the application of RF power to the upper electrode ranges from 10 MHz to 200 MHz, for example 60 MHz. Additionally, a typical frequency for the application of power to the substrate holder 20 ranges from 0.1 MHz to 30 MHz, for example 2 MHz. Moreover, the controller 55 is coupled to the RF generator 72 and the impedance match network 74 in order to control the application of RF power to the upper electrode 70.

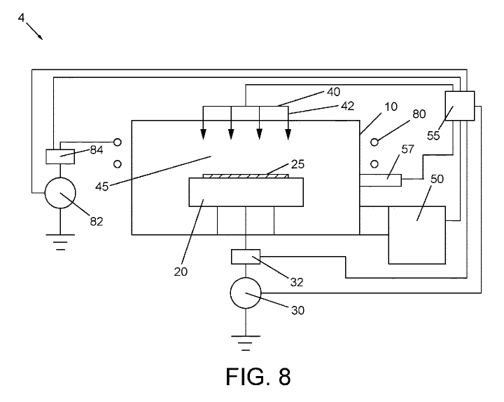

FIG. 8 schematically shows a plasma processing system configured for processing a high-k layer according to still another embodiment of the invention. The plasma processing system 4 of FIG. 8 includes the components of system 1 depicted in and described with reference to FIG. 5, and further includes an inductive coil 80 to which RF power is coupled via an RF generator 82 through an impedance match network 84. RF power is inductively coupled from the inductive coil 80 through a dielectric window (not shown) to the plasma-processing region 45. A typical frequency for the application of RF power to the inductive coil 80 ranges from 10 MHz to 100 MHz, for example 13.56 MHz. Similarly, a typical frequency for the application of power to the substrate holder 20 ranges from 0.1 MHz to 30 MHz, for example 13.56 MHz. In addition, a slotted Faraday shield (not shown) can be employed to reduce capacitive coupling between the inductive coil 80 and plasma. Moreover, the controller 55 is coupled to the RF generator 82 and the impedance match network 84 in order to control the application of power to the inductive coil 80.

In an alternate embodiment, the plasma is formed using electron cyclotron resonance (ECR). In yet another embodiment, the plasma is formed from the launching of a Helicon wave. In yet another embodiment, the plasma is formed from a propagating surface wave.

Numerous modifications and variations of the invention are possible in light of the above teachings. It is therefore to be understood that, within the scope of the appended claims, the invention may be practiced otherwise than as specifically described herein.

What is claimed is:

1. A method for forming a thin high-k layer on a substrate, the method comprising:
providing a substrate in a process chamber;
depositing a high-k material to at least a minimum thickness to form a thick complete high-k layer on the substrate; and
thinning the thick complete high-k layer to a desired thickness less than the minimum thickness to form a thin complete high-k layer.

2. The method according to claim 1, wherein the high-k material comprises Ta₂O₅, TiO₂, ZrO₂, Al₂O₃, Y₂O₃, HfSiOₓ, HfO₂, ZrSiOₓ, TaSiOₓ, SrOₓ, SrSiOₓ, LaOₓ, LaSiOₓ, YOₓ, or YSiOₓ, or a combination of two or more thereof.

3. The method according to claim 1, wherein the minimum thickness of the thick complete high-k layer is between about 30 Å and about 200 Å.

4. The method according to claim 1, wherein the minimum thickness of the thick complete high-k layer is between about 50 Å and about 100 Å.

5. The method according to claim 1, wherein the depositing comprises thermal chemical vapor deposition, plasma-enhanced chemical vapor deposition, atomic layer deposition, or physical vapor deposition.

6. The method according to claim 1, wherein the desired thickness of the thin complete high-k layer is between about 5 Å and about 50 Å.

7. The method according to claim 1, wherein the desired thickness of the thin complete high-k layer is between about 10 Å and about 30 Å.

8. The method according to claim 1, wherein the providing comprises providing a substrate having an interface layer formed on the substrate and the depositing comprises depositing the high-k material on the interface layer.

9. The method according to claim 8, wherein the interface layer comprises an oxide layer, a nitride layer, or an oxynitride layer, or a combination of two or more thereof.

10. The method according to claim 1, wherein the thinning comprises exposing the deposited high-k layer to a plasma process.

11. The method according to claim 10, wherein the plasma process comprises a process gas containing an inert gas.

12. The method according to claim 11, wherein the inert gas comprises He, Ne, Ar, Kr, or Xe, or a combination of two or more thereof.

13. The method according to claim 11, wherein the process gas further comprises a reactive gas.

14. The method according to claim 13, wherein the reactive gas comprises HCl, HBr, Cl₂, Br₂, CₓH_{y}X_{z}, or CₓH_{y}X_{z}, or a combination of two or more thereof.

15. The method according to claim 10, wherein the plasma process comprises etching the thick complete high-k layer in a reactive etching process.

16. The method according to claim 10, wherein the plasma process comprises modifying a portion of the thick complete high-k layer and removing the modified portion using wet processing.

17. A method for forming a thin hafnium-containing high-k layer on a substrate, the method comprising:
providing a substrate in a process chamber, the substrate having an interface layer formed thereon;
depositing a hafnium-containing high-k material to at least a minimum thickness necessary to form a thick complete hafnium-containing high-k layer on the interface layer in a TCVD process; and
thinning the thick complete hafnium-containing high-k layer to a desired thickness less than the minimum thickness to form a thin complete hafnium-containing high-k layer.

18. The method according to claim 17, wherein the minimum thickness of the thick complete hafnium-containing high-k layer is between about 30 Å and about 200 Å.

19. The method according to claim 17, wherein the desired thickness of the thin complete hafnium-containing high-k layer is between about 5 Å and about 50 Å.

20. The method according to claim 17, wherein the thinning comprises etching the deposited hafnium-containing high-k layer in a reactive etching process.

21. The method according to claim 17, wherein the thinning comprises modifying a portion of the thick complete hafnium-containing high-k layer in a plasma process and removing the modified portion using wet processing.
